(19) United States
(12) Patent Application Publication
(10) Pub. No.: US 2026/0230071 A1
(43) Pub. Date: Aug. 6, 2026

(54) Methods, Systems, and Devices for Controlling Current Leakage of Data Interfaces

(71) Applicant: PARADE TECHNOLOGIES, LTD, San Jose, CA (US)

(72) Inventors: Hongquan Wang, Shanghai (CN); Yaru Sun, Nanjing (CN); Yuanping Chen, Cupertino, CA (US); Liang Chang, Shanghai (CN)

(21) Appl. No.: 19/043,159

(22) Filed: Jan. 31, 2025

(51) Int. Cl. H03K 17/16

(52) U.S. Cl. CPC H03K 17/161

(57) ABSTRACT

This application is directed to controlling current leakage in a USB sideband use mode of a data interface of an electronic device. The electronic device includes a power supply interface configured to receive a power supply signal. The electronic device also includes a signal interface configured to exchange input/output signals with a computer device. The electronic device further includes a driver circuit coupled to the signal interface. The driver circuit is powered via a driver supply port and configured to provide an output signal via the signal interface. The electronic device further includes a power control component coupled to the power supply interface, the signal interface, and the driver supply port. The power control component is configured to electrically decouple the power supply interface from the driver supply port when a voltage level of the power supply interface is lower than a voltage level of the signal interface.

### TECHNICAL FIELD

The disclosed embodiments relate generally to data transmission technology, including methods, devices, and interfaces for controlling current leakage in a sideband use channel of a data interface of an electronic device.

### BACKGROUND

Many electronic devices are physically coupled to each other and communicate with each other using data links and interfaces in compliance with an industry bus standard, which specifies physical interfaces and protocols for connecting, data transferring, and powering of hosts. For example, a sink device communicates with a source device via sideband use (SBU) pins of a connector under a USB (Universal Serial Bus) protocol. The SBU pins connect the source device via direct current (DC) coupling. An input signal, which is received by the sink device via the SBU pins, generates different voltage levels based on pull-up and pull-down resistances. In particular, when the sink device is powered off, the input signal is applied on these resistances, causing a leakage (e.g., current) between a power supply of the source device and a ground of the sink device that is powered off and reducing the reliability of the sink device.

### SUMMARY

In accordance with some embodiments of this application is at least a realization of a need to eliminate or reduce a current leakage between power supplies of a source device (e.g., a computer device) and a sink device (e.g., an electronic device) when the source device and the sink device are coupled to one another via a data interface (e.g., a USB interface). One solution is to implement a power switch component configured to control the data interface coupling between a power supply of a sink device and a power supply of a source device. In an example, the power switch component includes one or more switching transistors (e.g., P-type metal-oxide-semiconductor field-effect transistors (P-type MOSFETs)) and a comparator. The comparator is configured to generate a control signal configured to control the one or more switching transistors based on whether a power supply of the sink device is enabled or disabled. In some situations, when the power supply of the sink device is enabled to power the sink device, the control signal generated by the comparator turns on the one or more switching transistors to allow circuitries associated with the sink device to be powered by its own power supply. When the power supply of the sink device is disabled from powering the sink device, the control signal generated by the comparator turns off the one or more switching transistors to decouple the disabled power supply of the sink device from the source device, thereby reducing a current leakage via the data interface of the source device and the sink device (e.g., from an active power supply of the source device to the disabled power supply of the sink device).

In one aspect of this application, an electronic device for controlling leakage current includes a power supply interface configured to receive a power supply signal. The electronic device further includes a signal interface configured to exchange input/output signals with a computer device. The electronic device further includes a driver circuit coupled to the signal interface. The driver circuit is powered via a driver supply port and configured to provide an output signal via the signal interface. The electronic device further includes a power control component coupled to the power supply interface, the signal interface, and the driver supply port. The power control component is configured to electrically decouple the power supply interface from the driver supply port when a voltage level of the power supply interface is lower than a voltage level of the signal interface.

In another aspect of this application, an interface of an electronic device for reducing leakage current includes a power supply interface configured to receive a power supply signal. The interface further includes a signal interface configured to exchange input/output signals with a computer device. The interface further includes a driver circuit coupled to the signal interface. The driver circuit is powered via a driver supply port and configured to provide an output signal via the signal interface. The interface further includes a power control component coupled to the power supply interface, the signal interface, and the driver supply port. The power control component is configured to electrically decouple the power supply interface from the driver supply port when a voltage level of the power supply interface is lower than a voltage level of the signal interface.

In another aspect of this application, a method for controlling leakage current includes providing a power supply interface configured to receive a power supply signal. The method further includes providing a signal interface configured to exchange input/output signals with a computer device. The method further includes providing a driver circuit coupled to the signal interface. The driver circuit is powered via a driver supply port and configured to provide an output signal via the signal interface. The method further includes providing a power control component coupled to the power supply interface, the signal interface, and the driver supply port. The power control component is configured to electrically decouple the power supply interface from the driver supply port when a voltage level of the power supply interface is lower than a voltage level of the signal interface.

These illustrative embodiments are mentioned not to limit or define the disclosure, but to provide examples to aid understanding thereof. Additional embodiments are discussed in the Detailed Description, and further description is provided there.

### BRIEF DESCRIPTION OF THE DRAWINGS

For a better understanding of the various described embodiments, reference should be made to the Description of Embodiments below, in conjunction with the following drawings in which like reference numerals refer to corresponding parts throughout the figures.

FIG. 1 is a block diagram of an example electronic system in which electronic devices are electrically connected via a data link, in accordance with some embodiments.

FIG. 2 is an example PCI Express electronic system in which a first electronic device or component is electrically coupled to a second electronic device or component via a data link, in accordance with some embodiments.

FIGS. 3A and 3B are two example electronic systems in which a data link is coupled between two electronic devices or components and includes at least one retimer, in accordance with some embodiments.

FIG. 4 is a block diagram an example electronic system in which a first electronic device or component is electrically coupled to a second electronic device or component via a data link, in accordance with some embodiments.

FIG. 5 is a block diagram of an example sideband use channel of an electronic device including a power control component, in accordance with some embodiments.

FIG. 6 is a block diagram of an example sideband use channel of an electronic device including an example driver circuit, in accordance with some embodiments.

FIG. 7 is a block diagram of an example circuitry of a power control component of a sideband use channel, in accordance with some embodiments.

FIG. 8 is a waveform diagram of example signals produced by a power control component coupled to a power supply interface that is disabled from providing power, in accordance with some embodiments.

FIG. 9 is a flow diagram of an example method providing an electronic device for controlling a current leakage via a data interface, in accordance with some embodiments.

Like reference numerals refer to corresponding parts throughout the several views of the drawings.

### DESCRIPTION OF EMBODIMENTS

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

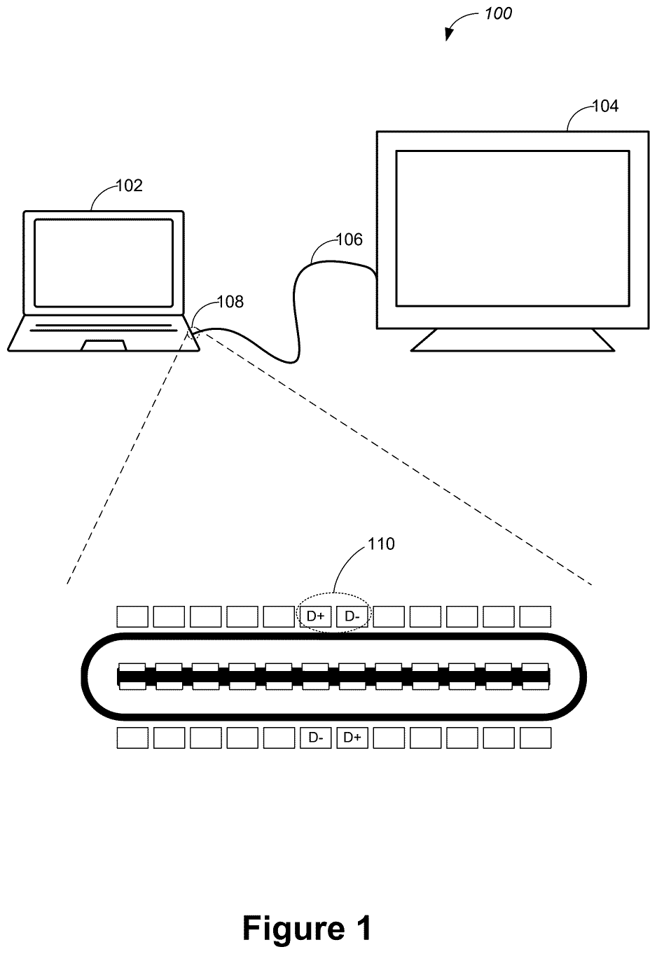

FIG. 1 is a block diagram of an example electronic system 100 in which a first electronic device 102 is electrically coupled to a second electronic device 104 via a data link 106, in accordance with some embodiments. The first electronic device 102 and second electronic device 104 are configured to exchange data via the data link 106. In some embodiments, the first electronic device 102 includes a video source, and the second electronic device 104 includes a display device. The display device has a screen configured to display visual content provided by the first electronic device 102 via the data link 106. In another example not shown, the first electronic device 102 is a desktop computer and the second electronic device 104 is a mobile phone that exchanges data with the desktop computer via the data link 106. Examples of the electronic devices 102 and 104 include, but are not limited to, a desktop computer, a laptop computer, a tablet computer, a video player, a camera device, a gameplayer device, and other formats of electronic devices that are configured to provide data or receive data. Video data, audio data, text, program data, control data, configuration data, or any other data is transmitted between the first and second electronic devices 102 and 104 via the data link 106.

Connectors 108 include connectors incorporated into electronic devices as well as connectors at the ends of cables, such as the data link cable 106. The data link cable 106 includes a connector 108 at each end. The two data link connectors 108 are configured to connect the data link 106 to respective connectors 108 of the first electronic device 102 and second electronic device 104. In some embodiments, the connectors 108 are DisplayPort connectors having a digital display interface developed by a consortium of personal computer and chip manufacturers and standardized by the Video Electronics Standards Association (VESA). The DisplayPort connectors are configured to connect the data link 106 to the first electronic device 102 and carry video, audio, and control data according to a data communication protocol. In another example, the connectors 108 are universal serial bus (USB) connectors (e.g., configured to connect a computer to a peripheral device). Exemplary types of USB connectors include, but are not limited to, USB-A, USB-B, USB-C, USB Micro-A, USB Micro-B, USB Mini-B, USB 3.0A, USB 3.0B, USB 3.0 Micro B, and USB Micro-AB. Further, a data communication protocol of USB4 is applied to communicate data using a USB-C connector, thereby providing a throughput of up to 40 Gbps, power delivery of up to 100 W, support for 4K and 5K displays, and backward compatibility with USB 3.2 and USB 2.

In some embodiments, the connectors 108 include a bidirectional channel for communicating a stream of data between the first and second electronic devices 102 and 104. The bidirectional channel of the connectors 108 include two data lanes and a pair of differential pins 110 coupled to the two data lanes. The pair of differential pins 110 is configured to receive a differential input signal from the first electronic device 102 or the second electronic device 104, and the differential input signal carries a serial data command or serial content data (e.g., video or audio data) that is communicated via the two data lanes of the connectors 108. As such, the two data lanes and pair of differential pins 110 of the connectors 108 are configured to facilitate bidirectional communication between the first electronic device 102 and the second electronic device 104. The bidirectional channel is a data channel or an auxiliary channel. Specifically, the auxiliary channel of the connectors 108 is used for communication of additional serial data beyond video and audio data, such as consumer electronics control (CEC) commands. In some embodiments, the pair of differential pins 110 is coupled to a dedicated set of twisted-pair wires configured to carry two input signals of the differential input signal.

Each connector 108 of the data link 106 is configured to be coupled to a respective connector 108 of the first electronic device 102 or a respective connector 108 of the second electronic device 104. Each connector 108 of the data link 106 is bidirectional, and so is each connector 108 of the electronic devices 102 and 104. When a connector 108 of the data link 106 is coupled to the first or second electronic device 102 or 104, the pair of differential pins 110 of the connector 108 of the data link 106 is physically and electrically coupled to a pair of differential pins 110 of the connector 108 of the first or second electronic device 102 or 104. The pair of differential pins 110 of the connector 108 of the first or second electronic device 102 or 104 is configured to receive data from, or transmit data to, the differential pins 110 of the connector 108 of the data link 106.

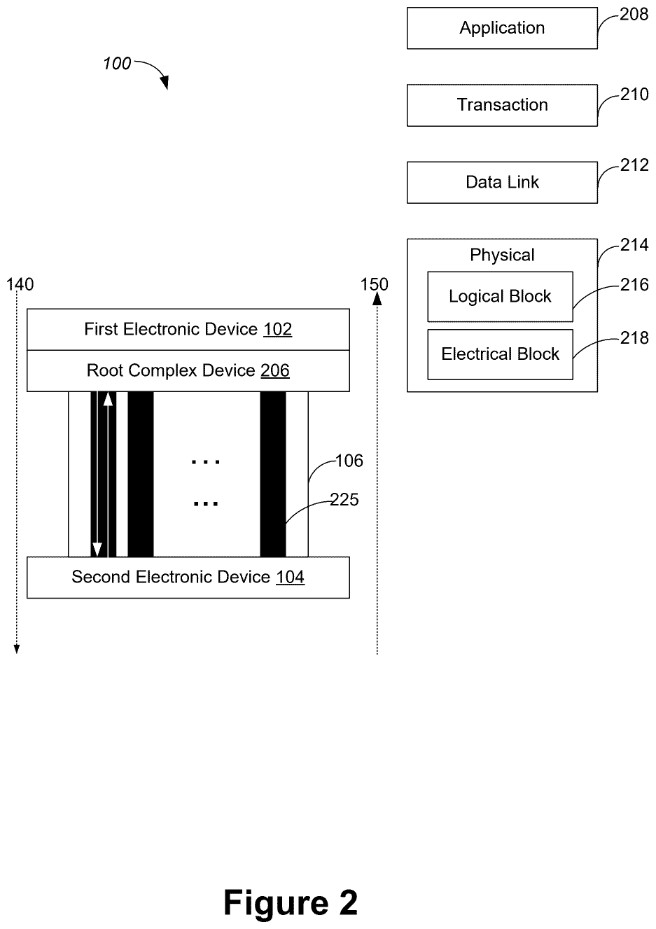

FIG. 2 is an example PCI Express electronic system 100 in which a first electronic device or component 102 is electrically coupled to a second electronic device or component 104 via a data link 106, in accordance with some embodiments. In an example, the first electronic device 102 includes a central processing unit (CPU) of a personal computer, and the second electronic device 104 is a peripheral component of the personal computer, such as a graphics card, a hard drive, a solid state drive, a Wi-Fi communication module, or an Ethernet card. The data link 106 includes a connection port for receiving from the second electronic device 104. The connection port is optionally formed on the mother board of the personal computer. The data link 106 complies with PCI Express (i.e., PCIe), which is a high-speed serial computer expansion bus standard, and provides an interface to communicate data packets between the first and second electronic devices 102 and 104 in compliance with the PCI Express. The data link 106 is a serial data bus including one or more data transmission channels 225. Each channel 225 includes two wire sets for transmitting and receiving data packets, thereby supporting full-duplex communication between the first and second electronic devices 102 and 104. In some examples, the data link 106 has 1, 4, 9, or 16 channels 225 coupled in a single data port of the data link 106. For each lane, the two wire sets correspond to a downstream data direction 140 or an upstream data direction 150 (defined with respect to the first electronic device 102). In some embodiments, each wire set includes two wires for carrying a pair of differential signals.

In some embodiments, the first electronic device 102 includes or is coupled to a root complex device 206 that is further coupled to the data link 106. The root complex device 206 is configured to generate requests for transactions including a series of one or more packet transmissions on behalf of the first electronic device 102. Examples of the transactions include, but are not limited to, Memory Read, Memory Read Lock, IO Read, IO Write, Configuration Read, Configuration Write, and Message. In some embodiments, the first electronic device 102 is coupled to one or more additional electronic devices besides the second electronic device 104. The data link 106 includes one or more switch devices to couple the root complex device 206 of the first electronic device 102 to multiple endpoints including the second electronic device 104 and additional electronic devices not shown in FIG. 1.

PCI Express is established based on a layered model including an application layer 208, a transaction layer 210, a data link layer 212, and a physical layer 214. As the top layer, the application layer 208 is implemented in software programs, such as Ethernet, NVMe, SOP, AHCI, and SATA. In the transaction layer 210, each transaction of a series of packet transmissions is implemented as requests and responses separated by time. For example, a memory-related transaction is translated to device configuration and control data transferred to or from the second electronic device 104 (e.g., a memory device). Data packets associated with each transaction are managed by data flows on the data link layer 212. The physical layer 214 of PCI Express controls link training and electrical (analog) signaling, and includes a logical block 216 and an electrical block 218. The logical block 216 defines ordered data sets in training states, and the electrical block 218 defines eye diagram characteristics and analog waveforms. Each layer of the layered model includes first specifications for a transmitting end where a root complex device 206 is coupled and second specifications for a receiving end where a peripheral component (i.e., the second electronic device 104) is coupled.

As high frequency signals are transmitted within the channels 225 of the data link 106, these signals are distorted and spread over sequential symbols and result in inter symbol interferences (ISI) and bit errors at the receiving end of the second electronic device 104. These ISI and bit errors can be suppressed by a feed-forward equalizer (FFE) that is coupled serially on a path of the data link 106 and configured with equalization settings using an equalization procedure. In an example, the FFE includes a finite impulse response (FIR) filter. The equalization procedure is implemented when a high-speed data transfer rate needs to be initialized, when an equalization request is issued from the application layer 208, or when a BER (bit error rate) exceeds a data error tolerance. In some embodiments, initiation and termination of the equalization procedure are detected on the physical layer 214 based on data packets transferred over the data link 106.

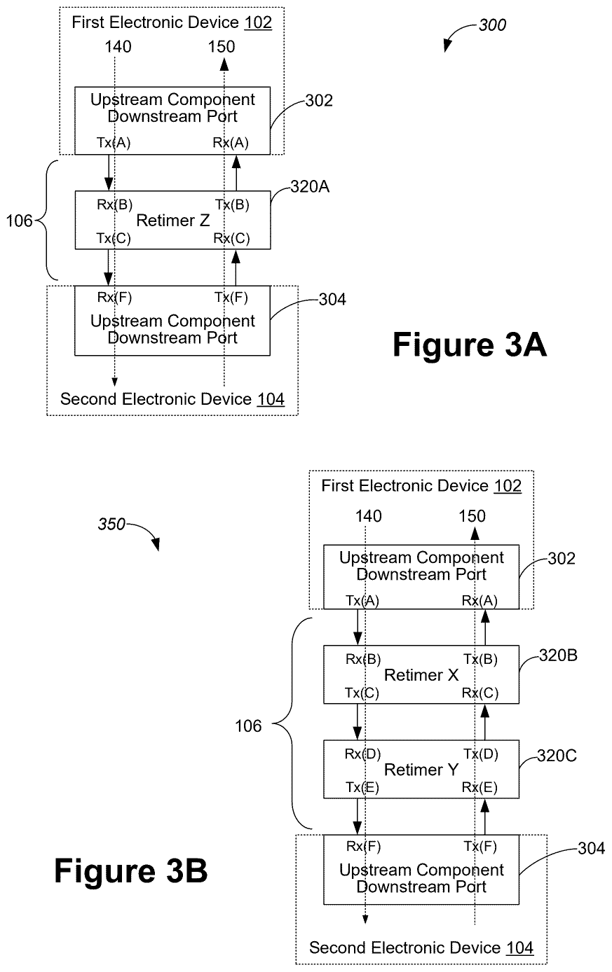

FIGS. 3A and 3B are two example electronic systems 300 and 350 in which a data link 106 is coupled between two electronic devices or components 102 and 104 and includes at least one retimer 320 (e.g., the retimers 320A, 320B, and 320C), in accordance with some embodiments. A retimer 320 is a mixed-signal device that is configured to transmit data packets actively (i.e., extract an embedded clock and recover the data packets in compliance with a bus standard, such as PCI Express). In an example, the retimer has a continuous time linear equalizer (CTLE), a wideband gain stage, and one or more of a clock and data recovery (CDR) circuit, a decision feedback equalizer (DFE), and a finite impulse response (FIR) driver. A state machine and/or a microcontroller is used in the retimer 320 to manage the CTLE, the wideband gain stage, the DFE, and the FIR driver, and implement a link training and status state machine (LTSSM).

The data link 106 enables bidirectional data communication between the electronic devices 102 and 104. A first electronic device 102 includes an upstream component 302 having a transmitting interface Tx(A) and a receiving interface Rx(A), and a second electronic device 104 includes a downstream component 304 having a receiving interface Rx(F) and a transmitting interface Tx(F). Each retimer 320 of the data link 106 is coupled between the electronic devices 102 and 104, and has a receiving interface Rx and a transmitting interface Tx for each of the downstream data direction 140 and the upstream data direction 150. Referring to FIG. 3A, the data link 106 includes only one retimer 320A. In some embodiments, the retimer 320A is disposed in proximity to the upstream component 302 of the first electronic device 102 or the downstream component 304 of the second electronic device 104. The receiving interface Rx(B) and the transmitting interface Tx(B) of the retimer 320A are coupled to the transmitting interface Tx(A) and receiving interface Rx(A) of the first electronic device 102, respectively. Another transmitting interface Tx(C) and another receiving interface Rx(C) of the retimer 320A are coupled to the receiving interface Rx(F) transmitting interface Tx(F) of the second electronic device 104, respectively. As such, data packets are transmitted between the electronic devices 102 and 104, either sequentially through the interfaces Tx(A), Rx(B), Tx(C), and Rx(F) on the downstream data direction 140 or sequentially through the interfaces Tx(F), Rx(C), Tx(B), and Rx(A) on the upstream data direction 150.

Referring to FIG. 3B, the data link 106 includes two retimers 320B and 320C that are electrically coupled in series between the first and second electronic devices 102 and 104. In an example, the first retimer 320B is disposed in proximity to the upstream component 302 of the first electronic device 102, and the second retimer 320C is disposed in proximity to the downstream component 304 of the second electronic device 104. A receiving interface Rx(B) and a transmitting interface Tx(B) of the first retimer 320B are coupled to the transmitting interface Tx(A) and receiving interface Rx(A) of the first electronic device 102, respectively. Another transmitting interface Tx(C) and another receiving interface Rx(C) of the first retimer 320B are coupled to a receiving interface Rx and a transmitting interface Tx of the second retimer 320C, respectively. Another transmitting interface Tx(E) and another receiving interface Rx(E) of the second retimer 320C are coupled to the receiving interface Rx(F) and transmitting interface Tx(F) of the second electronic device 104, respectively. As such, data packets are transmitted between the electronic devices 102 and 104, either sequentially through the interfaces Tx(A), Rx(B), Tx(C), Rx, Tx(E), and Rx(F) on the downstream data direction 140 or sequentially through the interfaces Tx(F), Rx(E), Tx, Rx(C), Tx(B), and Rx(A) on the upstream data direction 150.

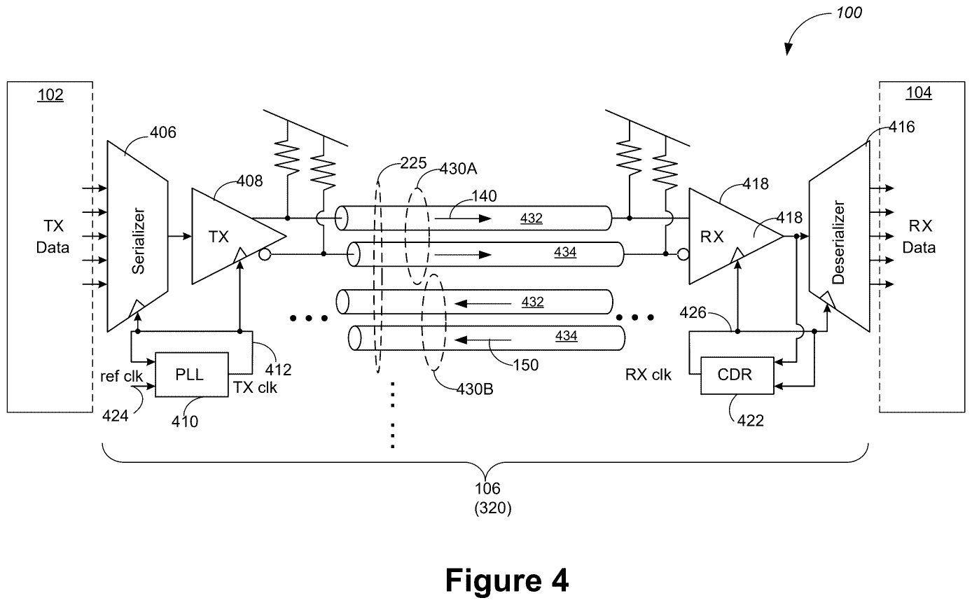

FIG. 4 is a block diagram of an example electronic system 100 in which a first electronic device or component 102 is electrically coupled to a second electronic device or component 104 via a data link 106, in accordance with some embodiments, and FIG. 4B is a block diagram of an example data link 106 including a plurality of modulation circuits, in accordance with some embodiments. In an example, the first electronic device 102 includes a central processing unit (CPU) of a personal computer, and the second electronic device 104 is a peripheral component of the personal computer, such as a graphics card, a hard drive, a solid state drive, a Wi-Fi communication module, or an Ethernet card. The data link 106 includes a connection port for receiving data from the second electronic device 104. The connection port is optionally formed on the mother board of the personal computer. In some embodiments, the data link 106 complies with a high-speed serial computer expansion bus standard (e.g., PCI Express (PCIe) or USB 4) and provides an interface to communicate data packets between the first and second electronic devices 102 and 104 in compliance with the bus standard. The data link 106 is a serial data bus including one or more data channels 225. In some embodiments, each data channel 225 includes two wire sets 430A and 430B (also called two data lanes) for transmitting and receiving data packets, respectively, thereby supporting full-duplex communication between the first and second electronic devices 102 and 104. In some examples, the data link 106 has 1, 4, 9, or 16 channels coupled in a single data port of the data link 106. For each data channel 225, the two wire sets 430A and 430B correspond to a downstream data direction 140 and an upstream data direction 150 defined with respect to the first electronic device 102, respectively. In some embodiments, each wire set 430A or 430B includes two respective wires 432 and 434 for carrying a pair of differential signals.

In some embodiments, the first electronic device 102 includes or is coupled to a root complex device (not shown) that is further coupled to the data link 106. The root complex device is configured to generate requests for transactions including a series of one or more packet transmissions on behalf of the first electronic device 102. Examples of the transactions include, but are not limited to, Memory Read, Memory Read Lock, Input Output (IO) Read, IO Write, Configuration Read, Configuration Write, and Message. In some embodiments, the first electronic device 102 is coupled to one or more additional electronic devices besides the second electronic device 104. The data link 106 includes one or more switch devices to couple the root complex device of the first electronic device 102 to multiple endpoints including the second electronic device 104 and additional electronic devices not shown in FIGS. 1 and 2.

A data transmission protocol (e.g., PCI Express, USB4 v2.0, or DisplayPort 2.1) is established based on a layered model including an application layer 208, a transaction layer 210, a data link layer 212, and a physical layer 214. As the top layer, the application layer 208 is implemented in software programs, such as Ethernet, NVMe, SOP, AHCI, and SATA. In the transaction layer 210, each transaction of a series of packet transmissions is implemented as requests and responses separated by time. For example, a memory-related transaction is translated to device configuration and control data transferred to or from the second electronic device 104 (e.g., a memory device). Data packets associated with each transaction are managed by data flows on the data link layer 212. The physical layer 214 controls link training and electrical (analog) signaling, and includes a logical block and an electrical block. The logical block 216 defines ordered data sets in training states, and the electrical block 218 defines eye diagram characteristics and analog waveforms. Each layer of the layered model includes first specifications for the transmitting side where a root complex device is coupled and second specifications for the receiving side where a peripheral component (i.e., the second electronic device 104) is coupled.

As signals are transmitted within the wire sets 430A and 430B of each data channel 225 of the data link 106, the signals are distorted and spread over sequential symbols. This results in inter symbol interferences (ISI) and bit errors at the receiving side of the second electronic device 104. In some embodiments, these ISI and bit errors can be suppressed by a feed-forward equalizer (FFE) that is coupled serially on a path of the data link 106 and configured with equalization settings using an equalization procedure. For example, an equalization procedure is implemented when a high-speed data transfer rate needs to be initialized, when an equalization request is issued from the application layer, or when the bit error rate (BER) exceeds the data error tolerance.

The electronic system 100 includes a serializer and deserializer (SERDES) system corresponding to the data link 106. The SERDES system of the data link 106 includes a serializer 406, a transmitter 408, the data channel 225, a receiver 418, and a deserializer 416. The serializer 406 converts parallel data received from the first electronic device 102 into serial data. The transmitter 408 sends the serial data to the data channel 225. The receiver 418 processes the serial data and sends the processed serial data to the deserializer 416, which converts the serial data back to the parallel data for the second electronic device 104. On the transmitting side, a phase lock loop 410 generates a transmitter clock signal 412 based on a reference clock signal 424, and the transmitter clock signal 412 is applied to control serialization of the data to be transmitted by the data channel 225 of the data link 106.

On the receiving side, a clock data recovery (CDR) circuit 422 is used to recover the receiver clock signal 426 from the serial data received via the data channel 225 and compensate for variation of signal amplitudes caused by loss and other factors in this data channel 225. In some embodiments, the CDR circuit 422 further includes a sampler and a clock recovery circuit. In some embodiments, the CDR circuit 422 is implemented based on one of: a phase-locked loop (PLL), a delay-locked loop (DLL), or a phase interpolator (PI). In some embodiments, the CDR circuit 422 satisfies a BER requirement corresponding to jitter tolerance. Additionally, the CDR circuit 422 complies with a communication interface standard (e.g., PCIe or USB4), is functional with spread spectrum clocking (SSC), and satisfies an electromagnetic interference (EMI) requirement. Under some circumstances, the CDR circuit 422 is configured to be applied in two or more data interfaces having different data rates and signal modulation schemes. The CDR circuit 422 is configurable (e.g., by offering a pull-in frequency range that is greater than a pull-in frequency range threshold and a jitter tolerance that is better than a jitter tolerance threshold). In some embodiments, the CDR circuit 422 is optimized in both of the pull-in frequency range and jitter tolerance.

The receiver clock signal 426 generated by the CDR 422 is used with the receiver 418 and the deserializer 416 to condition the serial data received via the data channel 225 and regenerate the parallel data from the serial data. During this process, the receiver 418 is configured to reduce (1) signal distortion, (2) data spreading over sequential symbols, (3) inter symbol interference (ISI), and (4) resulting bit errors of the serial data on the receiving side of the second electronic device 104. The receiver 418 is configured to generate an output data signal including the stream of data bits in an input data signal of the receiver 418. In some embodiments, the receiver 418 includes a signal conditioning front end applying one or more modulation circuits to compensate for loss from the data channel 225.

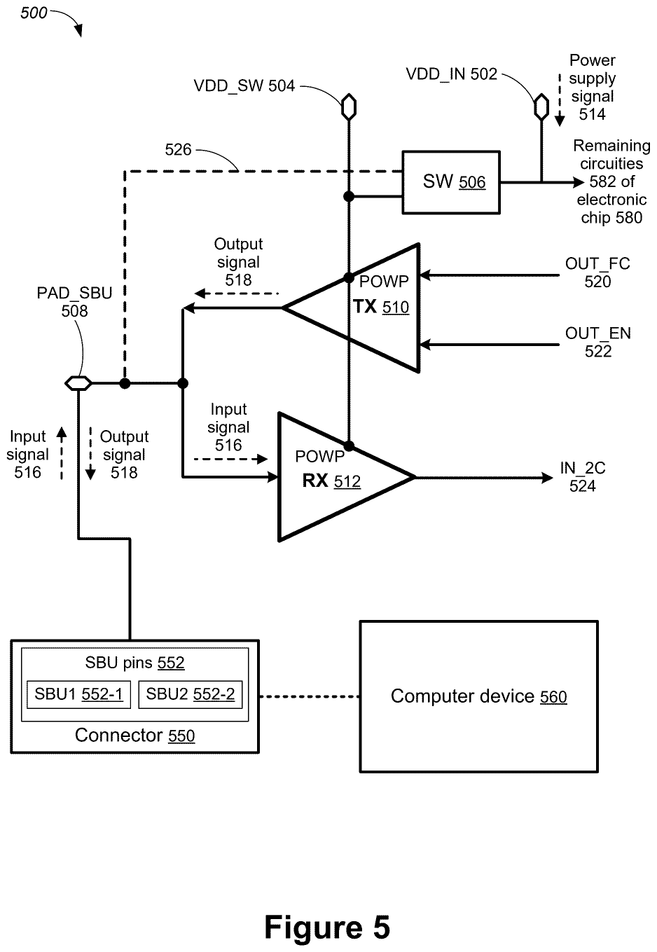

FIG. 5 is a block diagram of an example sideband use (SBU) channel 500 of an electronic device (e.g., second electronic devices 104 in FIGS. 1-4) including a power control component 506, in accordance with some embodiments. The electronic device is a sink device configured to communicate data with a source device (e.g., first electronic devices 102 and data links 106 in FIGS. 1-4), and the SBU channel 500 is generally part of a data interface of the sink device. In some embodiments, the SBU channel 500 is included in an electronic chip 580 included in the sink device. The SBU channel 500 bridges the electronic chip 580 with a connector 550 and exchanges signals with a source device (e.g., a computer device 560) via the connector 550. In some embodiments, the sink device includes an electronic device (e.g., the first electronic device 102 or the second electronic device 104 in FIG. 1). In some embodiments, the computer device 560 includes a laptop, a desktop, a workstation, a server, or other type. In some embodiments, the connector 550 is included in the connectors 108.

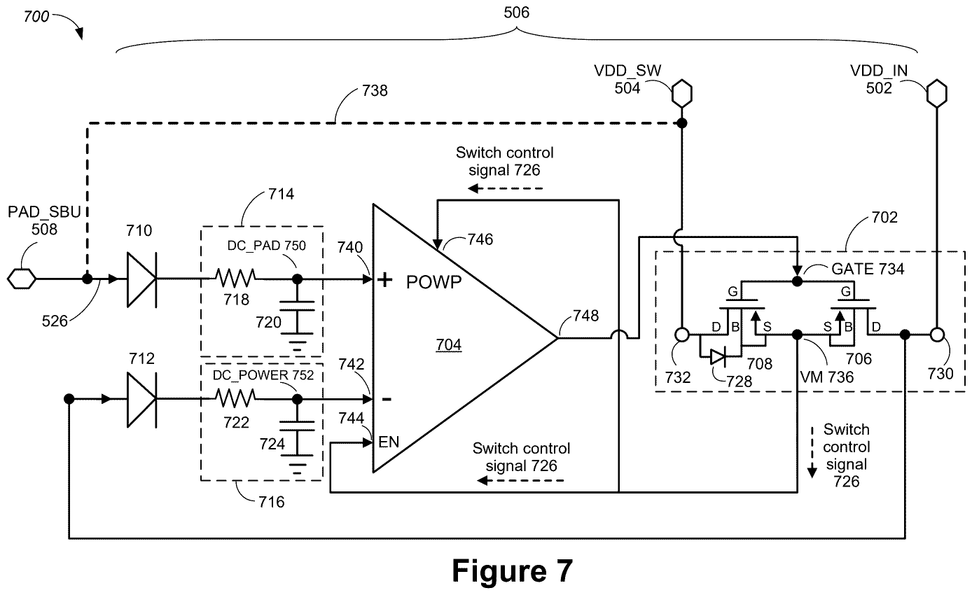

In some embodiments, the SBU channel 500 includes a power supply interface 502 (VDD_IN) configured to receive a power supply signal 514. The SBU channel 500 further includes a signal interface 508 (PAD_SBU) configured to exchange an input signal 516 and an output signal 518 with the computer device 560. The SBU channel 500 further includes a driver circuit 510 coupled to the signal interface 508 (PAD_SBU). The driver circuit 510 is powered via a driver supply port 504 (VDD_SW) configured to provide the output signal 518 via the signal interface 508 (PAD_SBU). The SBU channel 500 further includes the power control component 506 coupled to the power supply interface 502 (VDD_IN), the signal interface 508 (PAD_SBU), and the driver supply port 504 (VDD_SW). The power control component 506 is configured to electrically decouple the power supply interface 502 (VDD_IN) from the driver supply port 504 (VDD_SW) when a voltage level of the power supply interface 502 (VDD_IN) is lower than a voltage level of the signal interface 508 (PAD_SBU). In some embodiments, the voltage level of the power supply interface 502 (VDD_IN) is determined by the power supply signal 514. In some embodiments, the voltage level of the driver supply port 504 (VDD_SW) is determined by a power supply of the computer device 560. In some embodiments, the signal interface 508 (PAD_SBU) is electrically and/or communicatively coupled to the computer device 560 via the connector 550. The voltage level of the signal interface 508 (PAD_SBU) is determined by the computer device 560 (e.g., the voltage level of the signal interface 508 (PAD_SBU) is determined by the input signal 516 generated from the computer device 560). In some embodiments, the power supply interface 502 (VDD_IN) is used to power remaining circuities 582 of the electronic chip 580 (e.g., a remainder or a portion of the electronic chip 580) coupled to the SBU channel 500. In some embodiments, the signal interface 508 (PAD_SBU) is electrically coupled to the power control component 506 through a direct wire connection 526 (e.g., in FIG. 7).

In some embodiments, the driver circuit 510 of the SBU channel 500 includes an amplifier. In some embodiments, the driver circuit 510 receives a signal 520 (OUT_FC) and a signal 522 (OUT_EN). The signal 522 (OUT_EN) is a control signal that controls (e.g., enables or disables) the signal 520 (OUT_FC) inputted to the driver circuit 510. When the signal 522 (OUT_EN) is high, the signal 520 (OUT_FC) is transmitted to the signal interface 508 (PAD_SBU) via the driver circuit 510. In some embodiments, the signal 520 (OUT_FC) includes an output frequency-corrected signal that is stabilized or adjusted in compliance with a desired frequency specification (e.g., a characteristic frequency of the output signal 518). In some embodiments, the driver circuit 510 includes an entirety of a transmitter for the SBU channel 500. Alternatively, in some embodiments, the driver circuit 510 includes an output stage of a transmitter for the SBU channel 500, and a remainder (e.g., other stages) of the transmitter is not powered by the driver supply port 504 (VDD_SW).

In some embodiments, the SBU channel 500 further includes a receiver circuit 512 coupled to the signal interface 508 (PAD_SBU), the driver supply port 504 (VDD_SW), and the power supply interface 502 (VDD_IN). For example, the receiver circuit 512 may be coupled to the power supply interface 502 (VDD_IN) via the power control component 506. The receiver circuit 512 is configured to receive the input signal 516 via the signal interface 508 (PAD_SBU) and generate a signal 524 (IN_2C) from the input signal 516. The signal 524 (IN_2C) is a processed signal outputted by the receiver circuit 512 for subsequent circuitries. Further, in some embodiments, the receiver circuit 512 is configured to recover digital data signals carried by the input signal 516 by different signal processing techniques (e.g., filtering, amplification, etc.). In some embodiments, the receiver circuit 512 includes a power amplifier. In some embodiments, the receiver circuit 512 includes a receiver 418, a CDR circuit 422, and a deserializer 416 for the SBU channel 500 on a receiving side associated with a data link 106 (FIG. 4). Alternatively, in some embodiments, the receiver circuit 512 only includes a receiver 418 or an input amplifier of the receiver 418 (FIG. 4).

In some embodiments, each of the driver circuit 510 and the receiver circuit 512 is configured to be powered by the driver supply port 504 (VDD_SW) and the power supply interface 502 (VDD_IN) jointly. For example, when the driver supply port 504 (VDD_SW) is active (e.g., has a voltage level higher than that of the power supply interface 502 (VDD_IN)), the driver supply port 504 (VDD_SW) provides power to the driver circuit 510 or the receiver circuit 512, and the power control component 506 electrically couple the power supply interface 502 (VDD_IN) from the driver supply port 504 (VDD_SW). Conversely, when the driver supply port 504 (VDD_SW) has a voltage level lower than that of the power supply interface 502 (VDD_IN), e.g., when the driver supply port 504 (VDD_SW) is disabled, the driver circuit 510 or the receiver circuit 512 is electrically coupled to, and powered by, the power supply interface 502 (VDD_IN) by the power control component 506. By these means, the driver circuit 510 is either powered by the driver supply port 504 (VDD_SW) and the power supply interface 502 (VDD_IN), and will never by powered undesirably by the signal interface 508 (PAD_SBU), which is electrically coupled to a power supply of the computer device 560.

In some embodiments, the connector 550 includes a Universal Serial Bus (USB) port, and the signal interface 508 (PAD_SBU) is coupled to one or more Sideband Use (SBU) pins 552 of the USB port. In some embodiments, the one or more SBU pins 552 include a first SBU pin 552-1 (SBU1) and a second SBU pin 552-2 (SBU2). In some embodiments, the first SBU pin 552-1 and the second SBU pin 552-2 are low-speed, auxiliary signal lines of the USB port and support functions beyond standard USB data and power transmission, including sideband communication, auxiliary signaling, and/or other modes (e.g., DisplayPort, Thunderbolt, etc.). In some embodiments, the one or more SBU pins 552 of the connector 550 are coupled to the computer device 560 by direct current (DC) coupling.

In some embodiments, the USB port (e.g., the connector 550) corresponds to a protocol of USB 4.0. In some embodiments, the USB 4.0 is a technical specification of a USB data communication standard. In some embodiments, the USB 4.0 is built upon a plurality of protocols/standards (e.g., USB 3.2 and Thunderbolt 3) and aims to provide greater data transfer speed, enhanced device compatibility, and superior power delivery.

In some embodiments, the input signal 516 and output signal 518 exchanged at the signal interface 508 (PAD_SBU) have a frequency equal to or less than 10 MHz. In some embodiments, the one or more SBU pins 552 operate under a SBU mode at a frequency lower than that of primary high-speed data lanes of the connector 550 used for data transfer. In some embodiments, the one or more SBU pins 552 are used for auxiliary signaling operating within a frequency range of kilohertz (KHz) to low megahertz (MHz), thereby allowing the power control component 506 to control a power supply to be provided to drive the SBU channel 500 of a sink device.

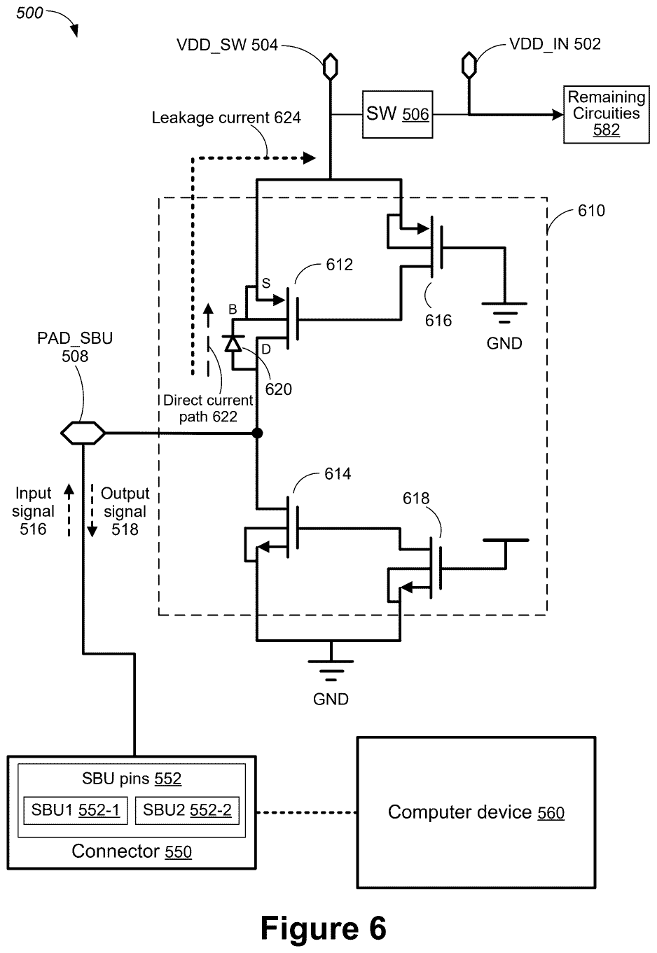

FIG. 6 is a block diagram of another example SBU channel 500 of an electronic device including a driver circuit 610, in accordance with some embodiments. The electronic device is a sink device configured to communicate data with a source device (e.g., first electronic devices 102 and data links 106 in FIGS. 1-4), and the SBU channel 500 is generally part of a data interface of the sink device. In particular, the driver circuit 610 is an example implementation of the driver circuit 510 (in FIG. 5). In some embodiments, the SBU channel 500 includes the signal interface 508 (PAD_SBU), the power supply interface 502 (VDD_IN), and the driver supply port 504 (VDD_SW), and the power supply interface 502 (VDD_IN) is coupled into the SBU channel 500 via a power control component 506. The driver circuit 610 is powered by the driver supply port 504 (VDD_SW). The power supply interface 502 (VDD_IN) receives a power supply signal, and is electrically coupled to the driver supply port 504 (VDD_SW) to drive the driver circuit 610 when a voltage level of the power supply interface 502 (VDD_IN) is higher than that of the signal interface 508 (PAD_SBU). The power supply interface 502 (VDD_IN) is decoupled from the driver supply port 504 (VDD_SW) when the voltage level of the power supply interface 502 (VDD_IN) is lower than that of the signal interface 508 (PAD_SBU).

In some embodiments, the driver circuit 610 includes a P-channel MOS (PMOS) transistor 612, an N-channel MOS (NMOS) transistor 614, a PMOS transistor 616, and a NMOS transistor 618. In some embodiments, the PMOS transistor 612 is coupled to the driver supply port 504 (VDD_SW) and the signal interface 508 (PAD_SBU). In some embodiments, a source and a drain of the PMOS transistor 612 are coupled to the driver supply port 504 (VDD_SW) and the signal interface 508 (PAD_SBU), respectively. In some embodiments, the example driver circuit 610 includes a multi-stage complementary metal-oxide-semiconductor (CMOS) amplifier. In some embodiments, the driver circuit 610 includes an operational amplifier.

In some embodiments, a parasitic diode 620 is formed between a drain and a body of the PMOS transistor 612. The parasitic diode 620 is an inherent feature of the PMOS transistor 612, because the drain of the PMOS transistor 612 is p-doped and the body of the PMOS transistor 612 is n-doped.

In some embodiments, when the signal interface 508 (PAD_SBU) receives the input signal 516 from the computer device 560 via the one or more SBU pins 552, the signal interface 508 (PAD_SBU) may have a higher voltage than the power supply interface 502 (VDD_IN). When the power supply interface 502 (VDD_IN) is electrically coupled to the transistor 612 and has a lower voltage than the signal interface 508 (PAD_SBU), e.g., by more than 0.5 V, the parasitic diode 620 is turned on and a direct and forward current path 622 is formed from the drain to the source of the transistor 612. A leakage current 624 associated with the input signal 516 flows, via the parasitic diode 620, from the signal interface 508 (PAD_SBU) to the driver supply port 504 (VDD_SW). The power control component 506 is turned on to enable the power supply interface 502 (VDD_IN) to drive the transistor 612, allowing the leakage current 624 to further flow from the driver supply port 504 (VDD_SW) to the power supply interface 502 and (VDD_IN) the remaining circuities 582 of the electronic chip 580. As such, in some embodiments, when the power supply interface 502 (VDD_IN) has a lower voltage than the signal interface 508 (PAD_SBU), the power control component 506 may be used to electrically decouple the power supply interface 502 (VDD_IN) from the transistor 612 and stop the leakage current 624 from running in the transistor 612, thereby preventing the signal interface 508 (PAD_SBU) or an associated computer device 560 from providing the leakage current 624.

In some embodiments, a voltage difference between the driver supply port 504 (VDD_SW) and the signal interface 508 (PAD_SBU) is smaller than a forward voltage (e.g., 0.5 V) of the parasitic diode 620. Stated another way, the voltage level of the driver supply port 504 (VDD_SW) is lower than the voltage level of the signal interface 508 (PAD_SBU) by no more than the forward voltage of the parasitic diode 620, and the parasitic diode 620 is not forward biased.

FIG. 7 is a block diagram of an example circuitry 700 of a power control component 506 of the SBU channel 500, in accordance with some embodiments. In particular, the example circuitry 700 of the power control component 506 is configured to prevent a leakage current 624. The example circuitry 700 of the power control component 506 prevents a voltage inversion between the signal interface 508 (PAD_SBU) and the power supply interface 502 (VDD_IN). In some embodiments, the power control component 506 is configured to electrically decouple the power supply interface 502 (VDD_IN) from the driver supply port 504 (VDD_SW), when the voltage level of the power supply interface 502 (VDD_IN) is lower than the voltage level of the signal interface 508 (PAD_SBU) (e.g., when the power supply interface 502 (VDD_IN) is in an OFF state). Such electrical decoupling avoids external current (e.g., the leakage current 624) flowing into the power supply interface 502 (VDD_IN), thereby improving safety and reducing leakage for the electronic chip 580. In some embodiments, the signal interface 508 (PAD_SBU) is electrically coupled to the power control component 506 through direct wire connection 526 (e.g., in reference to FIG. 5).

In some embodiments, the power control component 506 includes a switch component 702 and a comparator 704. The switch component 702 is coupled between the power supply interface 502 (VDD_IN) and the driver supply port 504 (VDD_SW). The comparator 704 is coupled to the switch component 702 and configured to generate a switch control signal 726 for controlling the switch component 702 based on a voltage difference between the signal interface 508 (PAD_SBU) and the power supply interface 502 (VDD_IN). In some embodiments, the switch control signal 726 acts as a power supply signal to provide power to the comparator 704. In some embodiments, the switch control signal 726 controls the comparator 704, e.g., enables the comparator 704 when the switch control signal 726 has a first voltage level (e.g., corresponding to “1”). In some embodiments, the switch control signal 726 is active, when the power supply interface 502 (VDD_IN) is active and in an ON state (e.g., when the power supply interface 502 (VDD_IN) provides a power supply voltage (e.g., 5 V)).

In some embodiments, a first input 730 of the switch component 702 is coupled to the power supply interface 502 (VDD_IN), a second input 732 of the switch component 702 is coupled to the driver supply port 504 (VDD_SW), a third input (GATE) 734 and an output 736 (VM) of the switch component 702 are coupled to the comparator 704. In some embodiments, a first input 740 (e.g., non-inverting (+) input node) of the comparator 704 is coupled to the signal interface 508 (PAD_SBU) via a first input node 750 (DC_PAD), a second input 742 (e.g., inverting (−) input node) of the comparator 704 is coupled to the power supply interface 502 (VDD_IN) via a second input node 752 (DC_POWER), a third input 744 (e.g., control/enable node) and a fourth input 746 (e.g., power supply node) of the comparator 704 are coupled to the output 736 of the switch component 702 to receive the switch control signal 726, and an output 748 of the comparator 704 is coupled to the third input 734 of the switch component 702.

In some embodiments, the switch component 702 includes one or more PMOS transistors. In some embodiments, the one or more PMOS transistors of the switch component 702 include a first PMOS transistor 706 and a second PMOS transistor 708. In particular, a drain of the first PMOS transistor 706 and a drain of the second PMOS transistor 708 form the first input 730 and the second input 732 of the switch component 702, respectively. A gate of the first PMOS transistor 706 and a gate of the second PMOS transistor 708 are connected to form the third input 734 of the switch component 702. A source of the first PMOS transistor 706 and a source of the second PMOS transistor 708 are connected to form the output 736 of the switch component 702. In some embodiments, the switch component 702 is configured to prevent current (e.g., the leakage current 624 in FIG. 6) from flowing into the remaining circuities 582 (FIG. 5) of the electronic chip 580 via the driver supply port 504 (VDD_SW) and the power supply interface 502 (VDD_IN).

In some embodiments, the power control component 506 includes a plurality of low-pass filters coupled to inputs of the comparator 704. Each low-pass filter has a characteristic frequency and configured to reduce noise coupled to a respective input of the comparator 704 based on the characteristic frequency. In some embodiments, the power control component 506 includes a first low-pass filter 714 (e.g., having a first resistor 718 and a first capacitor 720) and a second low-pass filter 716 (e.g., having a second resistor 722 and a second capacitor 724). The first low-pass filter 714 outputs signals at the first input node 750 (DC_PAD) and is coupled to the first input 740 of the comparator 704 and the signal interface 508 (PAD_SBU). The second low-pass filter 716 outputs signals at the second input node 752 (DC_POWER) and is coupled to the second input 742 of the comparator 704 and the power supply interface 502 (VDD_IN) (e.g., via the first input 730 of the switch component 702). In some embodiments, the first low-pass filter 714 and the second low-pass filter 716 are configured to prevent high-frequency disturbances of input signals from the power supply interface 502 (VDD_IN) and the signal interface 508 (PAD_SBU), respectively, after the input signals pass through a diode network (e.g., diodes 710 and 712 as discussed below). In some embodiments, the resistors (e.g., 718 and 722) and the capacitors (e.g., 720 and 724) are finely tuned to achieve cutoff frequencies of the first low-pass filter 714 and the second low-pass filter 716 close to a characteristic frequency of input signals (e.g., the input signal 516).

In some embodiments, the power control component 506 includes a plurality of diodes coupled to inputs of the comparator 704. In some embodiments, the power control component 506 includes a first diode 710 coupled between the signal interface 508 (PAD_SBU) and the first low-pass filter 714 and a second diode 712 coupled between the first input 730 of the switch component 702 and the second low-pass filter 716. In some embodiments, the first diode 710 and the second diode 712 are clamp diodes to protect the comparator 704 from damages caused by excessively high input voltages, e.g., clamping voltage levels of the first input 740 and the second input 742 of the comparator 704 at a certain voltage level within an allowable voltage range. In some embodiments, the first diode 710 and the second diode 712 are configured to transmit voltages (e.g., DC voltages) from the power supply interface 502 (VDD_IN) and the signal interface 508 (PAD_SBU). In some embodiments, the first diode 710 and the second diode 712 are configured provide isolation voltage levels for blocking reverse current.

In some embodiments, the comparator 704 is enabled and powered by the output 736 (VM) of the switch component 702. In some embodiments, the comparator 704 is enabled and powered by the switch control signal 726 that is generated at the output 736 of the switch component 702. In some embodiments, a voltage difference between the driver supply port 504 (VDD_SW) and the output 736 of the switch component 702 is smaller than 0.5 V. Stated another way, the voltage level of the driver supply port 504 (VDD_SW) is greater than the voltage level VM of the output 736 of the switch component 702 by no more than a forward voltage (e.g., 0.5 V, 0.35 V) of a parasitic diode 728 formed between a drain and a body of the second PMOS transistor 708.

In some embodiments, in accordance with a condition that the power supply interface 502 (VDD_IN) reaches a first voltage level (V1) and the signal interface 508 (PAD_SBU) reaches a second voltage level (V2) that is lower than the first voltage level (V1), the comparator 704 is configured to turn on the switch component 702 to electrically couple the power supply interface 502 (VDD_IN) and the driver supply port 504 (VDD_SW). Stated another way, in some embodiments, when the power supply interface 502 (VDD_IN) is in an ON state (e.g., the voltage level of the power supply interface 502 (VDD_IN) is at a high voltage), the voltage level of the power supply interface 502 (VDD_IN) reaches V1 and the voltage level of the signal interface 508 (PAD_SBU) reaches V2 that is lower than V1. A voltage level of the first input 740 of the comparator 704, which is determined by V2, is lower than a voltage level of the second input 742 of the comparator 704, which is determined by V1. Accordingly, the comparator 704 outputs a low voltage at the output 748 for the third input 734 of the switch component 702 to turn on the first PMOS transistor 706 and the second PMOS transistor 708 of the switch component 702. As such, the drain of the first PMOS transistor 706 and the drain (D) of the second PMOS transistor 708 are connected, and the switch component 702 electrically couples the power supply interface 502 (VDD_IN) and the driver supply port 504 (VDD_SW).

In some embodiments, in accordance with a condition that the power supply interface 502 (VDD_IN) reaches a first voltage level (V1) and that the signal interface 508 (PAD_SBU) reaches a second voltage level (V2) that is lower than the first voltage level (V1), the driver supply port 504 (VDD_SW) is electrically driven by the power supply interface 502 (VDD_IN) and reaches the first voltage level (V1). Stated another way, in some embodiments, when the power supply interface 502 (VDD_IN) is in an ON state (e.g., the power supply interface 502 (VDD_IN) provides a power supply signal (e.g., at 5 V)), the comparator 704 outputs a substantially low voltage, which is fed to the third input 734 of the switch component 702 to turn on the first PMOS transistor 706 and the second PMOS transistor 708 of the switch component 702. As such, the switch component 702 electrically couples the power supply interface 502 (VDD_IN) and the driver supply port 504 (VDD_SW), and the driver supply port 504 (VDD_SW) is electrically driven by the power supply interface 502 (VDD_IN) and reaches V1.

In some situations, V1 is approximately from 2.9 V to 3.7 V, and V2 is approximately from 2.9 V to 3.6 V.

Conversely, in some embodiments, in accordance with a condition that the power supply interface 502 (VDD_IN) reaches a first voltage level (V1′) and the signal interface 508 (PAD_SBU) reaches a second voltage level (V2′) that is higher than the first voltage level (V1′), the comparator 704 is configured to turn off the switch component 702 to electrically decouple the driver supply port 504 (VDD_SW) from the power supply interface 502 (VDD_IN). Stated another way, in some embodiments, when the power supply interface 502 (VDD_IN) is in an OFF state (e.g., the voltage level of the power supply interface 502 (VDD_IN) is floating or coupled to a low power supply voltage or ground), the voltage level of the power supply interface 502 (VDD_IN) reaches V1′ and the voltage level of the signal interface 508 (PAD_SBU) reaches V2′ that is lower than V1′. A voltage level of the first input 740 of the comparator 704, which is determined by V2′, is higher than a voltage level of the second input 742 of the comparator 704, which is determined by V1′. Accordingly, the comparator 704 outputs a substantially high voltage, which is fed to the third input 734 of the switch component 702 to turn off the first PMOS transistor 706 and the second PMOS transistor 708 of the switch component 702. As such, the drain of the first PMOS transistor 706 and the drain of the second PMOS transistor 708 are not electrically coupled (e.g., do not form a low resistance path having a resistance lower than a threshold resistance), and the switch component 702 electrically decouples the driver supply port 504 (VDD_SW) from the power supply interface 502 (VDD_IN). In some embodiments, when the power supply interface 502 (VDD_IN) is in an OFF state (e.g., grounded, floating, and coupled to a lower power supply voltage lower than ground), an electrical current (e.g., the leakage current 624 in FIG. 6) that flows from the signal interface 508 (PAD_SBU) to the power supply interface 502 (VDD_IN) via the power control component 506 is substantially reduced.

In some embodiments, in accordance with a condition that the power supply interface 502 (VDD_IN) reaches a first voltage level (V1′) and the signal interface 508 (PAD_SBU) reaches a second voltage level (V2′) that is higher than the first voltage level (V1′), the driver supply port 504 (VDD_SW) is electrically driven by the power supply interface 502 (VDD_IN) and reaches a third voltage level (V3′). A voltage difference between the third voltage level (V3′) and the second voltage level (V2′) is smaller than 0.5 V. For example, in some embodiments, when the power supply interface 502 (VDD_IN) is in an OFF state (e.g., the voltage level of the power supply interface 502 (VDD_IN) is at a low voltage), the comparator 704 outputs a high voltage at the output 748 for the third input 734 of the switch component 702 to turn off the first PMOS transistor 706 and the second PMOS transistor 708 of the switch component 702. As such, the switch component 702 electrically decouples the driver supply port 504 (VDD_SW) from the power supply interface 502 (VDD_IN). In particular, the driver supply port 504 (VDD_SW) is electrically driven by the signal interface 508 (PAD_SBU) via an electrical path 738 and reaches V3′. In some embodiments, the electrical path 738 is the direct current path 622 (in FIG. 6) formed by the PMOS transistor 612 of the example driver circuit 610 when the power supply interface 502 (VDD_IN) is in an OFF state (e.g., the voltage level of the power supply interface 502 (VDD_IN) is at a low voltage).

In some situations, V1′ is approximately from 0 mV to 0.05 mV (e.g., 50 μV), V2′ is approximately from 2.9 V to 3.7 V, and V3′ is approximately 2.5 V to 3.1 V. In some situations, V1′ is approximately at 0 V.

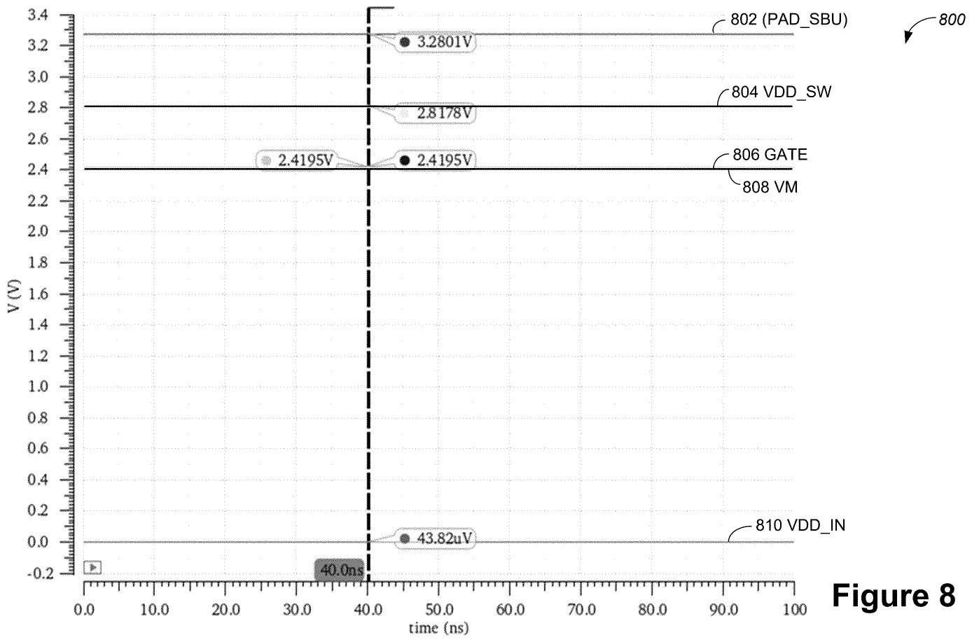

FIG. 8 is a temporal diagram 800 of example signals produced by a power control component 506 coupled to a power supply interface 502 (VDD_IN) that is disabled from providing power, in accordance with some embodiments. The temporal diagram 800 includes five voltage waveforms 802-810. A first voltage waveform 802 stabilizes at 3.2801 V, and represents a voltage level of a signal interface 508 (PAD_SBU). A second voltage waveform 804 stabilizes at 2.8178 V, and represents a voltage level of a driver supply port 504 (VDD_SW). A third voltage waveform 806 stabilizes at 2.4195 V, and represents a voltage level of a third input 734 of the switch component 702. A fourth voltage waveform 808 overlaps the third voltage waveform 806, stabilizes at 2.4195 V, and represents a voltage level of the switch component 702. A fifth voltage waveform 810 stabilizes at 43.82 μV, and represents a voltage level of the power supply interface 502 (VDD_IN).

In some embodiments, when the signal interface 508 (PAD_SBU) receives the input signal 516 (e.g., in FIG. 5) from the computer device 560 via the one or more SBU pins 552, the signal interface 508 (PAD_SBU) is driven at a high voltage (e.g., the voltage level PAD_SBU of 3.2801 V). Moreover, when the power supply interface 502 (VDD_IN) is in an OFF state, the power supply interface 502 (VDD_IN) is driven at a low voltage (e.g., the voltage level VDD_IN of 43.82 μV) and does not power the remaining circuities 582 (in FIG. 5) of the electronic chip 580. A voltage level of the first input 740 of the comparator 704, which is determined by the voltage level PAD_SBU of 3.2801 V, is higher than a voltage level of the second input 742 of the comparator 704, which is determined by the voltage level VDD_IN of 43.82 μV. Accordingly, the comparator 704 outputs a high voltage at the output 748 for the third input 734 of the switch component 702 (e.g., the voltage level GATE of 2.4195 V). The first PMOS transistor 706 and the second PMOS transistor 708 of the switch component 702 are turned on to electrically couple the drain of the first PMOS transistor 706 and the drain (D) of the second PMOS transistor 708, and the switch component 702 electrically couples the power supply interface 502 (VDD_IN) and the driver supply port 504 (e.g., the voltage level VDD_SW of 2.8178 V).

In some embodiments, the comparator 704 is enabled and powered by the output 736 (VM) of the switch component 702. For example, as shown in FIG. 8, the voltage level VM of the switch component 702 is at a high voltage of 2.4195 V, which enables and powers the comparator 704.

In some embodiments, a voltage difference between the driver supply port 504 (VDD_SW) and the output 736 of the switch component 702 is smaller than 0.5 V. For example, as shown in FIG. 8, the voltage level of the driver supply port 504 (VDD_SW) is at 2.8178 V, which is greater than the voltage level VM of 2.4195 V by no more than 0.5 V.

In some embodiments, when the power supply interface 502 (VDD_IN) is in an OFF state, a voltage difference between the driver supply port 504 (VDD_SW) and the signal interface 508 (PAD_SBU) is smaller than 0.5 V. For example, as shown in FIG. 8, the voltage level of the driver supply port 504 (VDD_SW) is at 2.8178 V, which is less than the voltage level PAD_SBU of 3.2801 V by no more than 0.5 V (e.g., corresponding to a forward voltage of a parasitic diode).

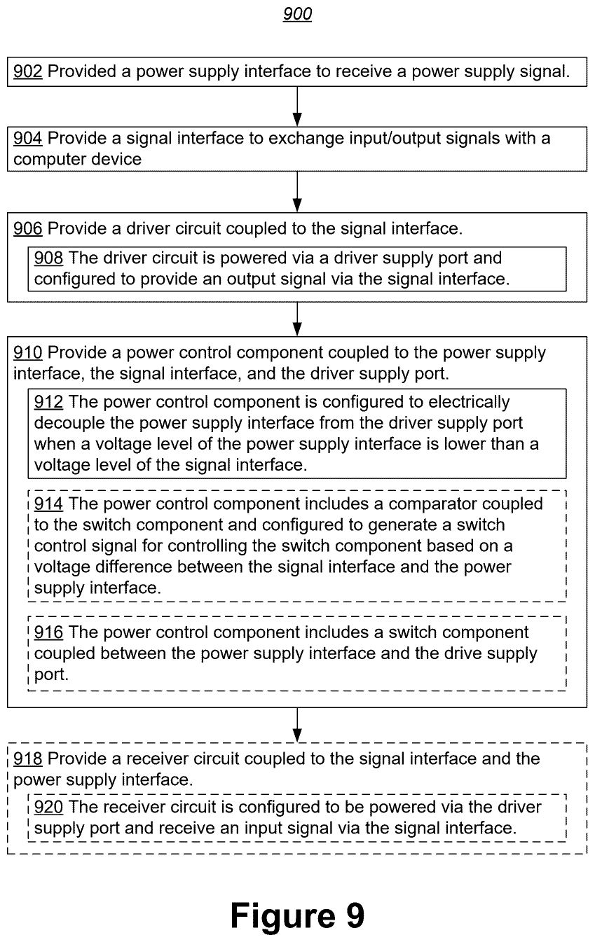

FIG. 9 is a flow diagram of an example method 900 providing an electronic device for controlling current leakage in a USB sideband use mode, in accordance with some embodiments. The electronic device includes a SBU channel 500, e.g. as a data interface to another electronic device. A power supply interface 502 (VDD_IN) is provided (operation 902) to receive a power supply signal 514. A signal interface 508 (PAD_SBU) is provided (operation 904) to exchange input/output signals (e.g., an input signal 516 and an output signal 518) with a computer device 560. A driver circuit 510 is provided (operation 906) to be coupled to the signal interface 508 (PAD_SBU). The driver circuit 510 is powered (operation 908) via a driver supply port 504 (VDD_SW) and configured to provide an output signal 518 via the signal interface 508 (PAD_SBU). A power control component 506 is provided (operation 910) to be coupled to the power supply interface 502 (VDD_IN), the signal interface 508 (PAD_SBU), and the driver supply port 504 (VDD_SW). The power control component 506 is configured to electrically decouple (operation 912) the power supply interface 502 (VDD_IN) from the driver supply port 504 (VDD_SW) when a voltage level of the power supply interface 502 (VDD_IN) is lower than a voltage level of the signal interface 508 (PAD_SBU).

In some embodiments, the power control component 506 includes (operation 914) a switch component 702 coupled between the power supply interface 502 (VDD_IN) and the driver supply port 504 (VDD_SW). The power control component 506 further includes (operation 916) a comparator 704 coupled to the switch component 702 and configured to generate a switch control signal 726 for controlling the switch component 702 based on a voltage difference between the signal interface 508 (PAD_SBU) and the power supply interface 502 (VDD_IN).

In some embodiments, a receiver circuit 512 is provided (operation 918), coupled to the signal interface 508 (PAD_SBU) and the power supply interface 502 (VDD_IN). The receiver circuit 512 is configured to be powered (operation 920) via the driver supply port 504 (VDD_SW) and receive an input signal 516 via the signal interface 508 (PAD_SBU).

In some embodiments, the switch component 702 includes one or more P-channel metal-oxide-semiconductor (PMOS) transistors (e.g., a first PMOS transistor 706 and a second PMOS transistor 708).

In some embodiments, the power control component 506 includes low-pass filters (e.g., a first low-pass filter 714 and a second low-pass filter 716) coupled to inputs (e.g., a first input 740 and a second input 742) of the comparator 704. Each low-pass filter (e.g., the first low-pass filter 714 or the second low-pass filter 716) has a characteristic frequency and configured to reduce noise coupled to a respective input (e.g., the first input 740 or the second input 742) of the comparator 704 based on the characteristic frequency.

In some embodiments, the comparator 704 is enabled and powered by an output of the switch component 702.

In some embodiments, a voltage difference between the driver supply port and the output 736 (VM) of the switch component is smaller than 0.5 V.

In some embodiments, in accordance with a condition that the power supply interface 502 (VDD_IN) reaches a first voltage level (V1) and the signal interface 508 (PAD_SBU) reaches a second voltage level (V2) that is lower than the first voltage level (V1) (e.g., when the power supply interface 502 (VDD_IN) is in an ON state), the comparator 704 is configured to turn on the switch component 702 to electrically couple the power supply interface 502 (VDD_IN) and the driver supply port 504 (VDD_SW).

In some embodiments, in accordance with a condition that the power supply interface 502 (VDD_IN) reaches a first voltage level (V1) and the signal interface 508 (PAD_SBU) reaches a second voltage level (V2) that is lower than the first voltage level (V1) (e.g., when the power supply interface 502 (VDD_IN) is in an ON state), the driver supply port 504 (VDD_SW) is electrically driven by the power supply interface 502 (VDD_IN) and reaches the first voltage level (V1).

In some embodiments, in accordance with a condition that the power supply interface 502 (VDD_IN) reaches a first voltage level (V1′) and the signal interface 508 (PAD_SBU) reaches a second voltage level (V2′) that is higher than the first voltage level (V1′) (e.g., when the power supply interface 502 (VDD_IN) is in an OFF state), the comparator 704 is configured to turn off the switch component 702 to electrically decouple the driver supply port 504 (VDD_SW) from the power supply interface 502 (VDD_IN).

In some embodiments, in accordance with a condition that the power supply interface 502 (VDD_IN) reaches a first voltage level (V1′) and the signal interface 508 (PAD_SBU) reaches a second voltage level (V2′) that is higher than the first voltage level (V1′) (e.g., when the power supply interface 502 (VDD_IN) is in an OFF state), the driver supply port 504 (VDD_SW) is electrically driven by the signal interface 508 (PAD_SBU) and reaches a third voltage level (V3′), and a voltage difference between the third voltage level (V3′) and the second voltage level (V2′) is smaller than 0.5 V.

In some embodiments, the driver circuit 510 (or an example driver circuit 610) includes a PMOS transistor 612. The PMOS transistor 612 is coupled to both the driver supply port 504 (VDD_SW) and the signal interface 508 (PAD_SBU).

In some embodiments, the driver supply port 504 (VDD_SW) and the signal interface 508 (PAD_SBU) are coupled to a source and a drain of the PMOS transistor 612, respectively. When the voltage level of the power supply interface 502 (VDD_IN) is lower than the voltage level of the signal interface 508 (PAD_SBU) (e.g., when the power supply interface 502 (VDD_IN) is in an OFF state), a direct current path 622 is formed from the drain to the source of the PMOS transistor 612.

In some embodiments, the signal interface 508 (PAD_SBU) is coupled to a Sideband Use (SBU) pin (e.g., the one or more SBU pins 552) of a Universal Serial Bus (USB) port.

In some embodiments, the USB port corresponds to a protocol of USB 4.0.

In some embodiments, the input/output signals (e.g., the input signal 516 and the output signal 518) exchanged at the signal interface 508 (PAD_SBU) has a frequency equal to or less than 10 MHz.

In accordance with some embodiments, an electronic device includes a power supply interface configured to receive a power supply signal. The electronic device further includes a signal interface configured to exchange input/output signals with a computer device. The electronic device further includes a driver circuit coupled to the signal interface. The driver circuit is powered via a driver supply port and configured to provide an output signal via the signal interface. The electronic device further includes a power control component coupled to the power supply interface, the signal interface, and the driver supply port. The power control component is configured to electrically decouple the power supply interface from the driver supply port when a voltage level of the power supply interface is lower than a voltage level of the signal interface.

In accordance with some embodiments, an interface of an electronic device includes a power supply interface configured to receive a power supply signal. The interface further includes a signal interface configured to exchange input/output signals with a computer device. The interface further includes a driver circuit coupled to the signal interface. The driver circuit is powered via a driver supply port and configured to provide an output signal via the signal interface. The interface further includes a power control component coupled to the power supply interface, the signal interface, and the driver supply port. The power control component is configured to electrically decouple the power supply interface from the driver supply port when a voltage level of the power supply interface is lower than a voltage level of the signal interface.

It should be understood that the particular order in which the operations in FIG. 9 has been described is merely exemplary and are not intended to indicate that the described order is the only order in which the operations could be performed. One of ordinary skill in the art would recognize various ways to control clock data recovery for a data communication channel. Additionally, it should be noted that details of other processes and structures described above with respect to FIGS. 1-8 are also applicable in an analogous manner to method 900 described above with respect to FIG. 9. For brevity, these details are not repeated here.

In some embodiments, the method 900 is governed by instructions that are stored on a non-transitory computer readable storage medium and that are executed by one or more processors of the electronic device. Each of the operations shown in FIG. 9 may correspond to instructions stored in a computer memory or non-transitory computer readable storage medium. The computer readable storage medium may include a magnetic or optical disk storage device, solid state storage devices such as Flash memory, or other non-volatile memory device or devices. The instructions stored on the computer readable storage medium may include one or more of: source code, assembly language code, object code, or other instruction format that is interpreted by one or more processors. Some operations in the method 900 may be combined and/or the order of some operations may be changed.

It will also be understood that, although the terms first and second are used, in some instances, to describe various elements, these elements are not limited by these terms. These terms are only used to distinguish one element from another. For example, a first electronic device can be termed a second electronic device, and, similarly, a second electronic device can be termed a first electronic device, without departing from the scope of the various described embodiments. The first electronic device and the second electronic device are both electronic devices, but they are not the same electronic device.

The terminology used in the description of the various described embodiments herein is for the purpose of describing particular embodiments only and is not intended to be limiting. As used in the description of the various described embodiments and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, the term “if” means “when” or “upon” or “in response to determining” or “in response to detecting” or “in accordance with a determination that,” depending on the context. Similarly, the phrase “if it is determined” or “if [a stated condition or event] is detected” means “upon determining” or “in response to determining” or “upon detecting [the stated condition or event]” or “in response to detecting [the stated condition or event]” or “in accordance with a determination that [a stated condition or event] is detected,” depending on the context.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software, or any combination thereof.

The above description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

What is claimed is:

1. An electronic device, comprising:
a power supply interface configured to receive a power supply signal;
a signal interface configured to exchange input/output signals with a computer device;
a driver circuit coupled to the signal interface, wherein the driver circuit is powered via a driver supply port and configured to provide an output signal via the signal interface; and
a power control component coupled to the power supply interface, the signal interface, and the driver supply port, wherein the power control component is configured to electrically decouple the power supply interface from the driver supply port when a voltage level of the power supply interface is lower than a voltage level of the signal interface.

2. The electronic device of claim 1, further comprising:
a receiver circuit coupled to the signal interface and the power supply interface, wherein the receiver circuit is configured to be powered via the driver supply port and receive an input signal via the signal interface.

3. The electronic device of claim 1, wherein the power control component includes:
a switch component coupled between the power supply interface and the drive supply port; and
a comparator coupled to the switch component and configured to generate a switch control signal for controlling the switch component based on a voltage difference between the signal interface and the power supply interface.

4. The electronic device of claim 3, wherein the switch component includes one or more P-channel metal-oxide-semiconductor (PMOS) transistors.

5. The electronic device of claim 3, wherein the power control component includes low-pass filters coupled to inputs of the comparator, and each low-pass filter has a characteristic frequency and configured to reduce noise coupled to a respective input of the comparator based on the characteristic frequency.

6. The electronic device of claim 3, wherein the comparator is enabled and powered by an output of the switch component.

7. The electronic device of claim 6, wherein a voltage difference between the driver supply port and the output of the switch component is smaller than 0.5 V.

8. The electronic device of claim 3, wherein:
in accordance with a condition that the power supply interface reaches a first voltage level and the signal interface reaches a second voltage level that is lower than the first voltage level, the comparator is configured to turn on the switch component to electrically couple the power supply interface and the driver supply port.

9. The electronic device of claim 3, wherein:
in accordance with a condition that the power supply interface reaches a first voltage level and the signal interface reaches a second voltage level that is lower than the first voltage level, the driver supply port is electrically driven by the power supply interface and reaches the first voltage level.

10. The electronic device of claim 3, wherein:
in accordance with a condition that the power supply interface reaches a first voltage level and the signal interface reaches a second voltage level that is higher than the first voltage level, the comparator is configured to turn off the switch component to electrically decouple the driver supply port from the power supply interface.

11. The electronic device of claim 3, wherein:
in accordance with a condition that the power supply interface reaches a first voltage level and the signal interface reaches a second voltage level that is higher than the first voltage level:
the driver supply port is electrically driven by the signal interface and reaches a third voltage level; and
a voltage difference between the third voltage level and the second voltage level is smaller than 0.5 V.

12. An interface device, comprising:
a power supply interface configured to receive a power supply signal;
a signal interface configured to exchange input/output signals with a computer device;
a driver circuit coupled to the signal interface, wherein the driver circuit is powered via a driver supply port and configured to provide an output signal via the signal interface; and
a power control component coupled to the power supply interface, the signal interface, and the driver supply port, wherein the power control component is configured to electrically decouple the power supply interface from the driver supply port when a voltage level of the power supply interface is lower than a voltage level of the signal interface.

13. The interface device of claim 12, wherein the driver circuit includes a PMOS transistor, and the PMOS transistor is coupled to both the driver supply port and the signal interface.

14. The interface device of claim 13, wherein the driver supply port and the signal interface are coupled to a source and a drain of the PMOS transistor, respectively, and when the voltage level of the power supply interface is lower than the voltage level of the signal interface, a direct current path is formed from the drain to the source of the PMOS transistor.

15. The interface device of claim 12, wherein the signal interface is coupled to a Sideband Use (SBU) pin of a Universal Serial Bus (USB) port.

16. The interface device of claim 15, wherein the USB port corresponds to a protocol of USB 4.0.

17. The interface device of claim 12, wherein the input/output signals exchanged at the signal interface has a frequency equal to or less than 10 MHz.

18. A method for controlling leakage current, comprising:
providing a power supply interface configured to receive a power supply signal;
providing a signal interface configured to exchange input/output signals with a computer device;
providing a driver circuit coupled to the signal interface, wherein the driver circuit is powered via a driver supply port and configured to provide an output signal via the signal interface; and
providing a power control component coupled to the power supply interface, the signal interface, and the driver supply port, wherein the power control component is configured to electrically decouple the power supply interface from the driver supply port when a voltage level of the power supply interface is lower than a voltage level of the signal interface.

19. The method of claim 18, further comprising:
providing a receiver circuit coupled to the signal interface and the power supply interface, wherein the receiver circuit is configured to be powered via the driver supply port and receive an input signal via the signal interface.

20. The electronic device of claim 18, wherein providing the power control component further comprises:
providing a switch component coupled between the power supply interface and the drive supply port; and
providing a comparator coupled to the switch component and configured to generate a switch control signal for controlling the switch component based on a voltage difference between the signal interface and the power supply interface.
